(19) United States
(12) Patent Application Publication
(10) Pub. No.: US 2025/0118650 A1
(43) Pub. Date: Apr. 10, 2025

(54) SEMICONDUCTOR PACKAGE

(71) Applicant: SAMSUNG ELECTRONICS CO., LTD., Suwon-si (KR)

(72) Inventor: Sunjae KIM, Suwon-si (KR)

(73) Assignee: SAMSUNG ELECTRONICS CO., LTD., Suwon-si (KR)

(21) Appl. No.: 18/659,539

(22) Filed: May 9, 2024

(30) Foreign Application Priority Data
Oct. 10, 2023 (KR) 10-2023-0134189

(51) Int. Cl. H01L 23/498; H01L 23/00; H01L 23/31; H01L 25/10; H01L 25/18

(52) U.S. Cl. CPC H01L 23/49838; H01L 23/3121; H01L 23/49833; H01L 24/16; H01L 24/32; H01L 24/73; H01L 25/105; H01L 25/18; H01L 2224/16145; H01L 2224/16225; H01L 2224/32145; H01L 2224/73204; H01L 2225/06513; H01L 2225/06517; H01L 2225/06589; H01L 2225/1041; H01L 2225/1094; H01L 2924/1431

(57) ABSTRACT

A semiconductor package includes a cover layer including a first surface contacting a lower chip structure and a second surface opposite to the first surface. The lower chip structure includes one or more stacked chips. The one or more stacked chips contact the first surface of the cover layer and include an upper surface having groove. The cover layer includes convex portions on the first surface that fill the grooves, and one or more concave portions on the second surface that are aligned on one or more convex portions.

### CROSS-REFERENCE TO RELATED APPLICATION

This application claims priority to Korean Patent Application No. 10-2023-0134189 filed on Oct. 10, 2023 in the Korean Intellectual Property Office, the disclosure of which being incorporated herein by reference in its entirety.

### BACKGROUND

Devices and apparatuses consistent with the present disclosure relates to a semiconductor package.

In accordance with the trend for lighter weight and higher performance in electronic devices, there may be demand for development of a semiconductor package including a chip structure in which a plurality of semiconductor chips are combined into one. In order to reduce a thicknesses of the semiconductor package, technology is being developed to minimize a thickness of the chip structure by applying a back grinding process.

### SUMMARY

It is an aspect to provide a semiconductor package having improved reliability.

According to an aspect of one or more embodiments, there is provided a semiconductor package comprising a lower redistribution structure including a lower redistribution layer; a lower chip structure disposed on the lower redistribution structure; a cover layer including a first surface that contacts the lower chip structure and a second surface that is opposite to the first surface; an encapsulant encapsulating at least a portion of the lower chip structure and at least a portion of the cover layer; an upper redistribution structure disposed on the encapsulant and including an upper redistribution layer; a plurality of posts that pass through the encapsulant and electrically connect the lower redistribution layer and the upper redistribution layer; and a plurality of external connection bumps that are disposed below the lower redistribution structure and electrically connect to the lower redistribution layer. The lower chip structure includes at least one stacked chip that contacts the first surface of the cover layer and has an upper surface having a plurality of grooves; a base chip disposed below the at least one stacked chip, the base chip including through-vias electrically connected to the at least one stacked chip and connection pads electrically connected to the lower redistribution layer; an adhesive layer disposed between the at least one stacked chip and the base chip and extending to the first surface of the cover layer along a side surface of the at least one stacked chip; and a mold surrounding an external side surface of the adhesive layer. The cover layer includes a plurality of convex portions on the first surface that fill the plurality of grooves, and at least one concave portion on the second surface that is aligned on at least one convex portion among the plurality of convex portions.

According to another aspect of one or more embodiments, there is provided a semiconductor package comprising a redistribution structure including a redistribution layer; a chip structure electrically connected to the redistribution layer and having an upper surface having a plurality of grooves; a cover layer including a first surface that contacts the upper surface of the chip structure, and a second surface that is opposite to the first surface and has at least one concave portion that is aligned with at least one groove among the plurality of grooves; an encapsulant encapsulating at least a portion of the chip structure and at least a portion of the cover layer; and a plurality of external connection bumps that are disposed below the redistribution structure and electrically connect to the redistribution layer. The plurality of grooves include a first groove having a first curvature, the at least one concave portion includes a first concave portion that is aligned on the first groove, and the first concave portion has a second curvature that is smaller than the first curvature.

According to yet another aspect of one or more embodiments, there is a semiconductor package comprising a lower redistribution structure including a lower redistribution layer; a lower chip structure including a lower surface on which connection terminals that are electrically connected to the lower redistribution layer are disposed, and an upper surface having a plurality of grooves; a cover layer including a first surface that contacts the upper surface of the lower chip structure, and a second surface that is opposite to the first surface and has at least one concave portion that is aligned with at least one groove among the plurality of grooves; an encapsulant encapsulating at least a portion of the lower chip structure and at least a portion of the cover layer; an upper redistribution structure disposed on the encapsulant and including an upper redistribution layer; and a plurality of posts that pass through the encapsulant and electrically connect the lower redistribution layer to the upper redistribution layer.

### BRIEF DESCRIPTION OF DRAWINGS

The above and other aspects will be more clearly understood from the following detailed description, taken in conjunction with the accompanying drawings, in which:

FIG. 1A is a cross-sectional view of a semiconductor package according to an example embodiment, FIG. 1B is a plan view of FIG. 1A, taken along line I-I′, and FIG. 1C is a partially enlarged view of portion ‘A’ of FIG. 1A;

FIG. 2 is a view illustrating a partially enlarged view corresponding to the portion ‘A’ of FIG. 1A, according to an example embodiment;

FIG. 3 is a view illustrating a partially enlarged view corresponding to the portion ‘A’ of FIG. 1A, according to an example embodiment;

FIG. 4 is a cross-sectional view of a semiconductor package according to an example embodiment.

FIG. 5A is a cross-sectional view of a semiconductor package according to an example embodiment, and FIG. 5B is a plan view of FIG. 5A, taken along line II-II′;

FIG. 6 is a cross-sectional view of a semiconductor package according to an example embodiment;

FIG. 7 is a cross-sectional view of a semiconductor package according to an example embodiment;

FIGS. 8A to 8G are views illustrating a process of manufacturing a semiconductor package according to an example embodiment.

### DETAILED DESCRIPTION

Hereinafter, various embodiments will be described with reference to the attached drawings. Unless otherwise specified, in this specification, terms such as ‘on,’ ‘upper portion,’ ‘upper surface,’ ‘below,’ ‘lower portion,’ ‘lower surface,’ ‘side surface,’ and the like may be based on the drawings, and may be actually changed depending on a direction in which a component is disposed.

Additionally, ordinal numbers such as “first,” “second,” “third,” or the like may be used as labels for specific elements, steps, directions, or the like to distinguish various elements, steps, directions, or the like from each other. Terms, not described using “first,” “second,” or the like in the specification, may still be referred to as “first” or “second” in the claims. Additionally, terms referenced by a particular ordinal number (e.g., “first” in a particular claim) may be described elsewhere with a different ordinal number (e.g., “second” in the specification or in another claim).

As used in this specification, the phrase “at least one of A, B, or C” includes within its scope “only A”, “only B”, “only C”, “A and B”, “B and C”, “A and C” and “all of A, B, and C.”

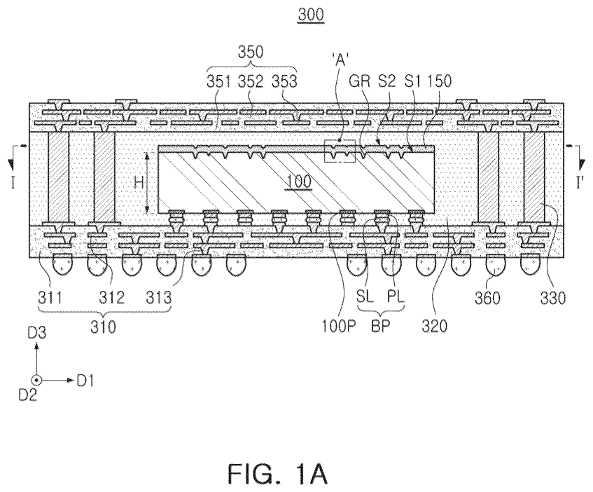

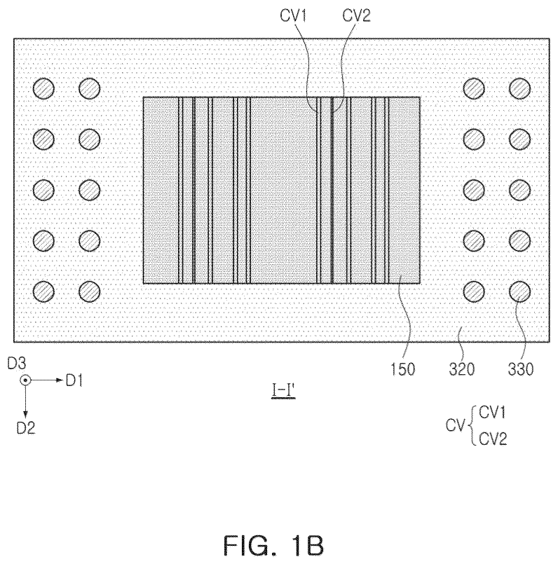

FIG. 1A is a cross-sectional view of a semiconductor package 300 according to an example embodiment, FIG. 1B is a plan view of FIG. 1A, taken along line I-I′, and FIG. 1C is a partially enlarged view of portion ‘A’ of FIG. 1A.

Referring to FIGS. 1A to 1C, a semiconductor package 300 of an example embodiment may include a lower chip structure 100, a cover layer 150, a lower redistribution structure 310, and an encapsulant 320. According to an embodiment, the semiconductor package 300 may further include a plurality of posts 330 and an upper redistribution structure 350. Hereinafter, the lower chip structure 100 and the lower redistribution structure 310 may also be referred to as a ‘chip structure’ and a ‘redistribution structure,’ respectively.

The lower chip structure 100 may be disposed on the lower redistribution structure 310, and may include first connection terminals 100P electrically connected to a lower redistribution layer 312. The first connection terminals 100P may be connected to the lower redistribution layer 312 through connection bumps BP disposed between the lower chip structure 100 and the lower redistribution structure 310. The connection bumps BP may include a pillar portion PL contacting the first connection terminals 100P, and a solder portion SL disposed below the pillar portion PL. The pillar portion PL may include copper (Cu) or an alloy of copper (Cu), and the solder portion SL may include a low melting point metal, for example, an alloy including tin (Sn) or tin (Sn). According to an embodiment, the connection bumps BP may include only one of the pillar portion PL or the solder portion SL. In other words, in some embodiments, one of the pillar portion PL or the solder portion SL may be omitted.

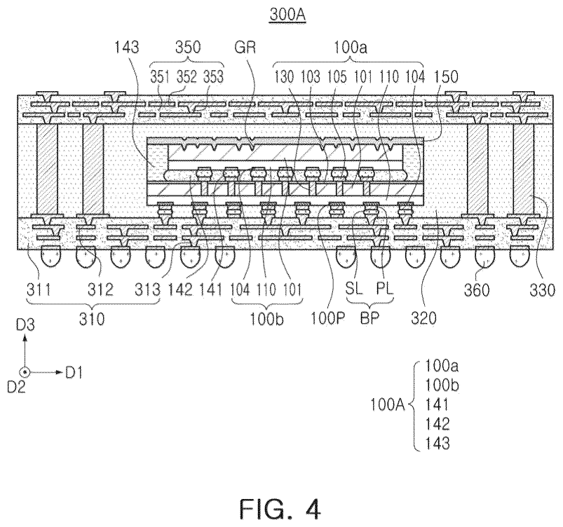

The lower chip structure 100 may include an integrated circuit (IC) and a semiconductor wafer formed of a semiconductor element such as silicon and germanium, or a compound semiconductor such as silicon carbide (SiC), gallium arsenide (GaAs), indium arsenide (InAs), and/or indium phosphide (InP). The lower chip structure 100 may be a bare semiconductor chip without a separate bump or a separate interconnection layer, but embodiments are not limited thereto, and in some embodiments, the lower chip structure 100 may be a packaged type semiconductor chip. The integrated circuit may be a memory circuit (or ‘memory chip’) including a logic circuit (or ‘logic chip’) such as a central processor (CPU), a graphics processor (GPU), a field programmable gate array (FPGA), an application processor (AP), a digital signal processor, a cryptographic processor, a microprocessor, a microcontroller, an analog-digital converter, an application specific integrated circuit (ASIC), or the like, a volatile memory such as a dynamic RAM (DRAM), a static RAM (SRAM), or the like, and/or a non-volatile memory such as a phase change RAM (PRAM), a magnetic RAM (MRAM), a resistive RAM (RRAM), a flash memory, or the like. According to an embodiment, the lower chip structure 100 may be a package structure including a plurality of semiconductor chips, which will be described later with reference to FIGS. 4 to 6.

The lower chip structure 100 may include a lower surface on which the first connection terminals 100P are disposed, and an upper surface having a plurality of grooves GR. The plurality of grooves GR may be formed by a back grinding process applied to the lower chip structure 100 to secure a form factor of the semiconductor package 300. In some embodiments, the plurality of grooves GR may be wheel scratches formed during the back grinding process. The plurality of grooves GR may extend to form straight lines and curves that are parallel or intersect each other. For example, the plurality of grooves GR may extend in a first direction (e.g., D2) on the upper surface of the lower chip structure 100. The plurality of grooves GR may be formed in a larger number than illustrated in the drawings. For example, in some embodiments, the plurality of grooves GR may be formed, for example, entirely on the upper surface of the lower chip structure 100.

The lower chip structure 100 may be back ground to have a height required to secure the form factor. A height (H) from the lower surface to the upper surface of the lower chip structure 100 may be about 300 μm or less. For example, in some embodiments, the height (H) may be about 100 μm to about 300 μm. In some embodiments, the height (H) may be about 120 μm to about 250 μm. In some embodiments, the height (H) may be about 130 μm to about 220 μm. However, embodiments are not limited to these heights.

The plurality of grooves GR may act as a crack seed during a pick-and-place process of the lower chip structure 100. In example embodiments, the cover layer 150 covering the upper surface of the lower chip structure 100 may be introduced to disperse stress concentrated in the plurality of grooves GR, and as a result, reliability and yield of the semiconductor package 300 may be improved.

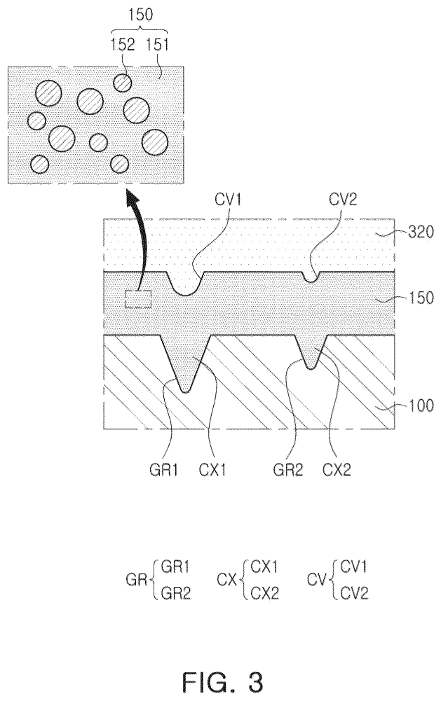

The cover layer 150 may be disposed on the lower chip structure 100. The cover layer 150 may be formed by a deposition process such as PVD or CVD, or a spin coating process. The cover layer 150 may extend along internal surfaces of the plurality of grooves GR of the lower chip structure 100. In some embodiments, the thickness of the cover layer 150 may be about 10 μm or less. For example, in some embodiments, the thickness may be about 1 μm to about 10 μm. In some embodiments, the thickness may be about 3 μm to about 10 μm. In some embodiments, the thickness may be about 5 μm to about 10 μm. However, embodiments are not limited to these ranges. The cover layer 150 may include silicon oxide (SiO), silicon nitride (SiN), silicon carbonitride (SiCN), or combinations thereof. According to an embodiment, the cover layer 150 may include a polymer (see FIG. 3).

As best seen in FIG. 3, the cover layer 150 may include a first surface S1 that contacts the upper surface of the lower chip structure 100, and a second surface S2 that is opposite to the first surface S1. The cover layer 150 may include convex portions CX on the first surface S1 that fill the plurality of grooves GR, and at least one concave portion CV on the second surface S2 that is aligned on at least one of the convex portions CX. The second surface S2 may be a flat surface to which a planarization process has been applied, but embodiments are not limited thereto.

Each of the convex portions CX may be aligned on a plurality of grooves GR corresponding thereto. Each of the concave portions CV may be aligned on convex portions CX corresponding thereto and a plurality of grooves GR corresponding thereto. In some embodiments, the number of grooves GR, the number of convex portions CX, and the number of concave portions CV may be the same, in which case each of the convex portions CX may be aligned on a respective one of the plurality of grooves and each of the concave portions CV may be aligned on a respective one of the convex portions CX and a respective one of the plurality of grooves, but embodiments are not limited thereto. According to an embodiment, the number of convex portions CX may be smaller than the number of grooves GR, and the number of concave portions CV may be smaller than the number of convex portions CX. The concave portions CV may have different widths, different depths, and different curvatures from the plurality of grooves GR, thereby dispersing stress concentrated in the plurality of grooves GR and preventing cracks from occurring. Therefore, the lower chip structure 100 of an example embodiment may have a level of strength that may ensure stability of a wafer. For example, the lower chip structure 100 on which the cover layer 150 is formed may have a strength of about 10 N or more in a strength evaluation according to a three-point bending test. The three-point bending test may be performed under conditions in which a size of a specimen (width×height) is approximately 10 mm×10 mm, a distance between supports supporting the specimen is about 6 mm, a radius of a tip pressing the specimen is about 0.25 mm, and a loading speed of the tip is approximately 1 mm/min. A bending strength of the lower chip structure 100 is not limited to the above-mentioned values, and may be changed depending on the conditions of the bending test.

In an embodiment, the plurality of grooves GR may include a first groove GR1 extending in a first direction D2. The convex portions CX may include a first convex portion CX1 filling the first groove GR1. The concave portions CV may include a first concave portion CV1 aligned on the first groove GR1. A width (w1) of the first concave portion CV1 in a second direction D1, perpendicular to the first direction D2, may be less than a width (W1) of the first groove GR1 in the second direction D1. In some embodiments, the width (w1) of the first concave portion CV1 may be a maximum width of the first concave portion CV1 in the second direction D1, and the width (W1) may be a maximum width of the first groove GR1 in the second direction D1. A depth (d1) of the first concave portion CV1 in a third direction D3, perpendicular to the second surface S2, may be less than a depth (D1) of the first groove GR1 in the third direction D3. In some embodiments, a curvature of the first concave portion CV1 may be smaller than curvature of the first groove GR1. In this case, the ‘curvature’ refers to a curvature of an internal curved surface (or curve) of each of the first concave portion CV1 and the first groove GR1 or a curvature on a lower portion of the internal curved surface (or curve) of each thereof.

In an embodiment, the plurality of grooves GR may include a second groove GR2 having a depth (D2), smaller than the depth (D1) of the first groove GR1. The convex portions CX may include a second convex portion CX2 filling the second groove GR2. The concave portions CV may include a second concave portion CV2 aligned on the second groove GR2. A depth (d2) of the second concave portion CV2 may be less than the depth (d1) of the first concave portion CV1. A width (w2) of the second concave portion CV2 in the second direction D1 may be less than a width (W2) of the second groove GR2 in the second direction D1. In some embodiments, the width (w2) of the second concave portion CV2 may be a maximum width of the second concave portion CV2 in the second direction D1, and the width (W2) may be a maximum width of the second groove GR2 in the second direction D1. The depth (d2) of the second concave portion CV2 in the third direction D3 may be less than the depth (D2) of the second groove GR2 in the third direction D3. A curvature of the second concave portion CV2 may be smaller than a curvature of the second groove GR2. In this case, the ‘curvature’ refers to curvature of an internal curved surface (or curve) of each of the second concave portion CV2 and the second groove GR2 or a curvature on a lower portion of the internal curved surface (or curve) of each thereof.

In example embodiments, the ‘curvature’ may be defined as a ratio of the depth (D1, D2, d1, or d2) and the width (W1, W2, w1, or w2) of each of the plurality of grooves GR and concave portions CV. For example, the curvature of the first concave portion CV1 may be defined as d1/w1, and the curvature of the first groove GR1 may be defined as D1/W1. The curvature of the second concave portion CV2 may be defined as d2/w2, and the curvature of the second groove GR2 may be defined as D2/W2. For example, the curvature (D1/W1 and D2/W2) of each of the plurality of grooves GR may be about 0.2 or more, and the curvature (d1/w1 and d2/w2) of each of the concave portions CV may be less than about 0.2.

Returning to FIG. 1A, the lower redistribution structure 310 may be a support substrate on which the lower chip structure 100 is mounted, and may include a lower insulating layer 311, lower redistribution layers 312, and a lower redistribution via 313.

The lower insulating layer 311 may be formed of an insulating material, for example, a thermosetting resin such as an epoxy resin, a thermoplastic resin such as polyimide, and/or a resin in which an inorganic filler or the like is impregnated into such resins, such as a prepreg, an Ajinomoto build-up film (ABF), or an FR-4, bismaleimide triazine (BT). For example, the lower insulating layer 311 may include a photosensitive resin such as a photoimageable dielectric (PID). The lower insulating layer 311 may include a plurality of insulating layers (not illustrated) stacked in the vertical direction D3. Depending on a process, a boundary between the plurality of insulating layers (not illustrated) may be unclear.

A lower redistribution layer 312 may be disposed on and in the lower insulating layer 311, and may redistribute the first connection terminal 100P of the lower chip structure 100. The lower redistribution layer 312 may include, for example, metal including copper (Cu), aluminum (Al), silver (Ag), tin (Sn), gold (Au), nickel (Ni), lead (Pb), titanium (Ti), or an alloy thereof. The lower redistribution layer 312 may perform various functions. For example, the lower redistribution layer 312 may include a ground pattern, a power pattern, and/or a signal pattern. In the case of a signal pattern, the signal pattern may provide a transmission path for various signals, for example, a data signal or the like, excluding the ground pattern, the power pattern, or the like. The lower redistribution layer 312 may include more or fewer redistribution layers than illustrated in the drawings. The lower redistribution layer 312 may include pads contacting the connection bumps BP and the plurality of posts 330.

The lower redistribution via 313 may extend within the lower insulating layer 311, and may be electrically connected to the lower redistribution layer 312. For example, the lower redistribution via 313 may interconnect lower redistribution layers 312 on different levels. The lower redistribution via 313 may include a signal via, a ground via, and/or a power via. The lower redistribution via 313 may include, for example, a metal material including copper (Cu), aluminum (Al), silver (Ag), tin (Sn), gold (Au), nickel (Ni), lead (Pb), titanium (Ti), or an alloy thereof. The lower redistribution via 313 may be a filled via in which a via hole is filled with a metal material, or a conformal via in which a metal material extends along an internal wall of the via hole.

A plurality of external connection bumps 360 may be disposed below the lower redistribution structure 310. The external connection bumps 360 may be electrically connected to the lower redistribution layer 312. The semiconductor package 300 may be connected to an external device such as a module substrate, a system board, or the like through the external connection bumps 360. According to an embodiment, the external connection bumps 360 may have a shape in which a pillar (or underbump metal) and a ball are combined. The pillar may include copper (Cu) or an alloy of copper (Cu), and the ball may include a low melting point metal, such as tin (Sn) or an alloy containing tin (Sn) (e.g., Sn—Ag—Cu). According to an embodiment, the external connection bumps 360 may include only the pillar or the ball. According to an embodiment, a resist layer may be formed on a lower surface of the lower redistribution structure 310 to protect the external connection bumps 360 from physical and chemical damage.

The encapsulant 320 may cover at least a portion of each of the lower chip structure 100 and the cover layer 150. The encapsulant 320 may cover a side surface of the lower chip structure 100 and a side surface of each of the plurality of posts 330. The encapsulant 320 may cover an upper surface of the cover layer 150, e.g., the second surface S2. The encapsulant 320 may include, for example, a thermosetting resin such as an epoxy resin, a thermoplastic resin such as polyimide, and/or a prepreg, an ABF, an FR-4, BT, an epoxy molding compound (EMC), or the like.

The plurality of posts 330 may be disposed around the lower chip structure 100 and may pass through the encapsulant 320 to electrically connect the lower redistribution layer 312 and an upper redistribution layer 352. The plurality of posts 330 may be formed of copper (Cu), nickel (Ni), titanium (Ti), lead (Pb), aluminum (Al), silver (Ag), gold (Au), platinum (Pt), or an alloy thereof. The plurality of posts 330 may extend in the vertical direction D3 within the encapsulant 320. The plurality of posts 330 may have a cylindrical shape, but embodiments are not limited thereto.

The upper redistribution structure 350 may be disposed on the encapsulant 320, and may include an upper insulating layer 351, upper redistribution layers 352, and an upper redistribution via 353.

The upper insulating layer 351 may include an insulating material, for example, a thermosetting resin such as an epoxy resin, a thermoplastic resin such as polyimide, and/or a resin in which an inorganic filler or the like is impregnated into such resins, such as a prepreg, an ABF, an FR-4, or BT. For example, the upper insulating layer 351 may include a photosensitive resin such as PID. The upper insulating layer 351 may include a plurality of insulating layers stacked in the vertical direction D3. Depending on a process, a boundary between the plurality of insulating layers may be unclear.

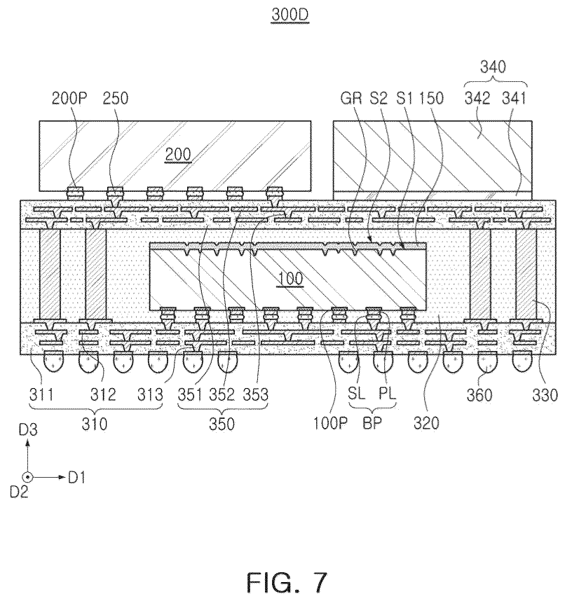

An upper redistribution layer 352 may be disposed on and in the upper insulating layer 351. The upper redistribution layer 352 may redistribute a chip structure mounted on the upper redistribution structure 350, for example, an upper chip structure 200 of FIG. 7. The upper redistribution layer 352 may include, for example, metal including copper (Cu), aluminum (Al), silver (Ag), tin (Sn), gold (Au), nickel (Ni), lead (Pb), titanium (Ti), or an alloy thereof. The upper redistribution layer 352 may include a ground pattern, a power pattern, and/or a signal pattern. The upper redistribution layer 352 may include more or fewer redistribution layers than illustrated in the drawings.

The upper redistribution via 353 may extend within the upper insulating layer 351, and be electrically connected to the upper redistribution layer 352. For example, the upper redistribution via 353 may interconnect upper redistribution layers 352 on different levels. The upper redistribution via 353 may include, for example, a metal material including copper (Cu), aluminum (Al), silver (Ag), tin (Sn), gold (Au), nickel (Ni), lead (Pb), titanium (Ti), or an alloy thereof. The upper redistribution via 353 may be a filled via in which a via hole is filled with a metal material, or a conformal via in which a metal material extends along an internal wall of the via hole.

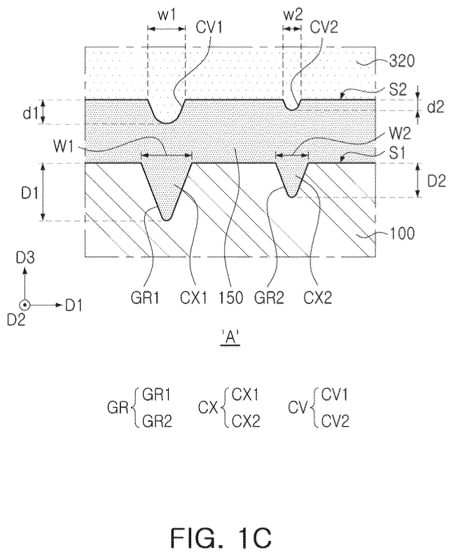

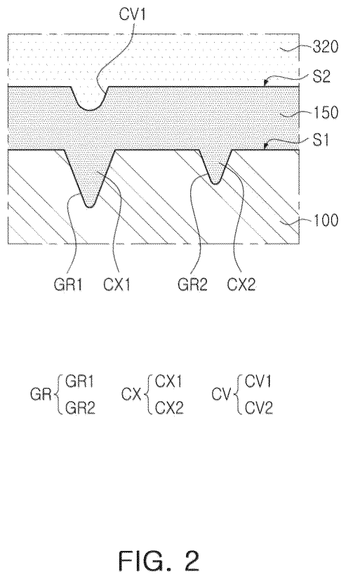

FIG. 2 is a view illustrating a partially enlarged view corresponding to the portion ‘A’ of FIG. 1A, according to an example embodiment.

Referring to FIG. 2, the cover layer 150 may include convex portions CX and concave portions CV in different numbers.

A plurality of grooves GR may include a first groove GR1 and a second groove GR2 having a depth that is less than a depth of the first groove GR1. The convex portions CX may include a first convex portion CX1 filling the first groove GR1, and a second convex portion CX2 filling the second groove GR2. The concave portions CV may include only a first concave portion CV1 aligned on the first groove GR1 and the first convex portion CX1. That is, as compared with FIG. 1C, in FIG. 2, the second concave portion CV2 of FIG. 1C may be omitted. The concave portions CV of the cover layer 150 may not include for example, a concave portion corresponding to the second groove GR2. A portion of the second surface S2 of the cover layer 150 that is over the second groove GR2 may be a flat surface to which a planarization process has been applied, but embodiments are not limited thereto.

FIG. 3 is a view illustrating a partially enlarged view corresponding to the portion ‘A’ of FIG. 1A, according to an example embodiment.

Referring to FIG. 3, the cover layer 150 may be formed using a polymer. The cover layer 150 may include an insulating resin 151 and a thermally conductive filler 152 dispersed in the insulating resin 151. The insulating resin 151 is not particularly limited, and may include a thermosetting resin such as an epoxy resin and/or a thermoplastic resin such as polyimide. The thermally conductive filler 152 is not particularly limited, and may include a conductive oxide particle, a metal particle, or mixed particles thereof. For example, aluminum oxide (Al₂O₃), zinc oxide (ZnO), indium tin oxide (ITO), or the like may be used as the conductive oxide particle, and a metal particle such as aluminum (Al), silver (Ag), iron (Fe), gold (Au), zinc (Zn), or the like may be used as metal particles. In this manner, since the cover layer 150 may include a material having excellent heat dissipation characteristics, thermal characteristics of the semiconductor package may be improved.

FIG. 4 is a cross-sectional view of a semiconductor package 300A according to an example embodiment.

Referring to FIG. 4, a semiconductor package 300A of an example embodiment may have the same or similar features as those described with reference to FIGS. 1A to 3, except that a lower chip structure (or ‘chip structure’) 100A in which a plurality of semiconductor chips are embedded is included. The plurality of semiconductor chips may include a base chip 100a and at least one stacked chip 100b.

At least a portion of the plurality of semiconductor chips (e.g., the base chip 100a in FIG. 4) may include through-vias 130 electrically connecting the plurality of semiconductor chips to each other. The plurality of semiconductor chips may be chiplets constituting a multi-chip module (MCM). Each of the plurality of semiconductor chips may include a central processor (CPU), a graphics processor (GPU), a field programmable gate array (FPGA), a digital signal processor (DSP), a cryptographic processor, a microprocessor, a microcontroller, an analog-digital converter, an application-specific integrated circuit (ASIC), a volatile memory, a non-volatile memory, an input/output (I/O) circuit, an analog circuit, a serial-parallel conversion circuit, or the like.

The chip structure 100A may include the base chip 100a and the at least one stacked chip 100b. For example, the base chip 100a may include a processor circuit, and the at least one stacked chip 100b may include at least one of an input/output circuit, an analog circuit, a memory circuit, or a serial-to-parallel conversion circuit, for the processor circuit. The base chip 100a and the at least one stacked chip 100b may be provided in larger numbers than illustrated in the drawings. For example, the at least one stacked chip 100b may include two or more semiconductor chips arranged horizontally and/or vertically on the base chip 100a.

The at least one stacked chip 100b may have an upper surface in which a plurality of grooves GR may be formed. For example, the at least one stacked chip 100b may have the plurality of grooves GR described with reference to FIGS. 1A to 1C. In some embodiments, the upper surface of the lower chip structure 100 illustrated in FIG. 1A may correspond to an upper surface of the at least one stacked chip 100b and an upper surface of a mold 143, and the first surface S1 of the cover layer 150 may be entirely in contact with an upper surface of the chip structure 100A. In other words, in some embodiments, the first surface S1 of the cover layer 150 may be in contact with the upper surface of the at least one stacked chip 100b and the upper surface of the mold 143.

The base chip 100a and the at least one stacked chip 100b may include a substrate 101, an upper protective layer 103, an upper pad 105, a circuit layer 110, a lower pad 104, and/or a through-via 130. The substrate 101 may include, for example, a semiconductor element such as silicon or germanium (Ge), or may include a compound semiconductor such as silicon carbide (SiC), gallium arsenide (GaAs), indium arsenide (InAs), or indium phosphide (InP). The substrate 101 may have a silicon-on-insulator (SOI) structure. The substrate 101 may have a conductive region, for example, a well doped with an impurity, or an active surface doped with an impurity and a non-active surface opposite thereto. The substrate 101 may include various device isolation structures, such as a shallow trench isolation (STI) structure.

The upper protective layer 103 may be formed on the non-active surface of the substrate 101, and may protect the substrate 101. The upper protective layer 103 may be formed as an insulating layer such as a silicon oxide film, a silicon nitride film, a silicon oxynitride film, or the like, but a material of the upper protective layer 103 is not limited to the above materials. For example, in some embodiments, the upper protective layer 103 may be formed of a polymer such as polyimide (PI). Although not illustrated in the drawings, a lower protective layer may be further formed on a lower surface of the circuit layer 110.

The upper pad 105 may be disposed on the upper protective layer 103. The upper pad 105 may include, for example, at least one of aluminum (Al), copper (Cu), nickel (Ni), tungsten (W), platinum (Pt), or gold (Au). The lower pad 104 may be disposed below the circuit layer 110, and may include a material, similar to a material of the upper pad 105. The materials of the upper pad 105 and lower pad 104 are not limited to the above materials. It can be understood that the lower pad 104 corresponds to the first connection terminals 100P described above.

The circuit layer 110 may be disposed on the active surface of the substrate 101, and may include various types of devices. For example, the circuit layer 110 may include may include various active and/or passive devices such as a field effect transistor (FET) such as a planar FET, FinFET, or the like, a memory device such as a flash memory, a dynamic random access memory (DRAM), a static random access memory (SRAM), an electrically erasable programmable read-only memory (EEPROM), a phase-change random access memory (PRAM), a magnetoresistive random access memory (MRAM), a ferroelectric random access memory (FeRAM), a resistive random access memory (RRAM), or the like, a logic device such as AND, OR, NOT, or the like, a system large scale integration (LSI), a CMOS imaging sensor (CIS), and/or a micro-electro-mechanical system (MEMS). The circuit layer 110 may include an interconnection structure electrically connected to the above-described elements, and an interlayer insulating layer surrounding the interconnection structure. The interlayer insulating layer may include silicon oxide or silicon nitride. The interconnection structure may include multilayer interconnections and/or vertical contacts. The interconnection structure may connect elements of the circuit layer 110 to each other, may connect elements to a conductive region of the substrate 101, or may connect elements to the through-via 130.

The through-via 130 may pass through the substrate 101 in the vertical direction (D3 direction), and may provide an electrical path connecting the upper pad 105 and the lower pads 104. The through-via 130 may include a conductive plug and a barrier film surrounding the same. The conductive plug may include metal, such as tungsten (W), titanium (Ti), aluminum (Al), or copper (Cu). The conductive plug may be formed by a plating process, a PVD process, or a CVD process. The barrier film may include an insulating barrier film and/or a conductive barrier film. The insulating barrier film may be formed of an oxide film, a nitride film, a carbide film, a polymer, or a combination thereof. The conductive barrier film may be disposed between the insulating barrier film and a conductive plug. The conductive barrier film may include a metal compound such as tungsten nitride (WN), titanium nitride (TiN), or tantalum nitride (TaN), for example. The barrier film may be formed by a PVD process or a CVD process.

Bumps 141 and an adhesive layer 142 may be disposed between the base chip 100a and the at least one stacked chip 100b. The bumps 141 may electrically connect the base chip 100a and the at least one stacked chip 100b. The bumps 141 may include tin (Sn), indium (In), bismuth (Bi), antimony (Sb), copper (Cu), silver (Ag), zinc (Zn), lead (Pb) and/or an alloy thereof, and, according to an embodiment, may have a form in which a metal pillar and a solder ball are combined. The adhesive layer 142 may surround each of the bumps 141, and may join the base chip 100a and the at least one stacked chip 100b. The adhesive layer 142 may be formed using a non-conductive film (NCF), but embodiments are not limited thereto, and in some embodiments, the adhesive layer 142 may be formed, for example, using any type of insulating film capable of a heat compression process. According to an embodiment, the adhesive layer 142 may cover at least a portion of a side surface of the at least one stacked chip 100b.

The mold 143 may be disposed on the base chip 100a and may surround an outer surface of the at least one stacked chip 100b and an outer surface of the adhesive layer 142. The mold 143 may include a thermosetting resin such as an epoxy resin, a thermoplastic resin such as polyimide, and/or a prepreg, an ABF, an FR-4, BT, an EMC, or the like. In some embodiments, the mold 143 may not provide grooves acting as a crack seed, such as the plurality of grooves GR provided by the at least one stacked chip 100b. Depending on a process, in some embodiments when grooves are formed on an upper surface of the mold 143, the cover layer 150 may further include convex portions and concave portions aligned with the grooves formed on the upper surface of the mold 143.

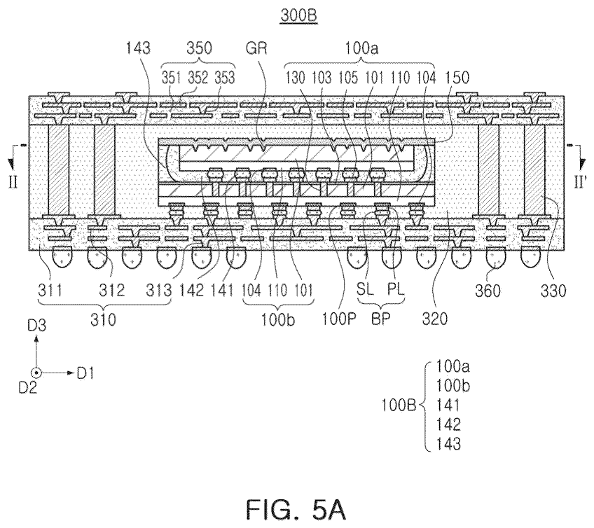

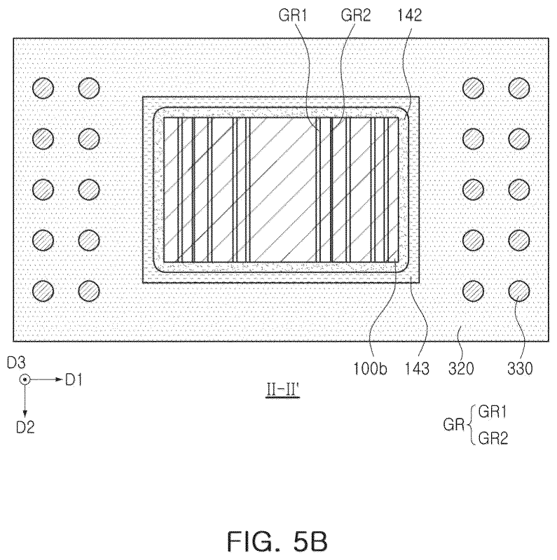

FIG. 5A is a cross-sectional view of a semiconductor package 300B according to an example embodiment, and FIG. 5B is a plan view of FIG. 5A, taken along line II-II′.

Referring to FIGS. 5A and 5B, a semiconductor package 300B of an example embodiment may have the same or similar features as those described with reference to FIGS. 1A to 4, except that a lower chip structure (or ‘chip structure’) 100B in which the adhesive layer 142 is in contact with the cover layer 150 is included.

The chip structure 100B may include the base chip 100a, the at least one stacked chip 100b, the bumps 141, the adhesive layer 142, and the mold 143. An upper surface of the at least one stacked chip 100b may be in contact with the first surface S1 of the cover layer 150, and may have a plurality of grooves GR. The adhesive layer 142 may be disposed between the at least one stacked chip 110b and the base chip 100a, and may extend along a side surface of the at least one stacked chip 100b to the first surface S1 of the cover layer 150.

When the adhesive layer 142 is exposed from the mold 143 (e.g., when an upper surface of the adhesive layer 142 is exposed unlike that shown in FIG. 5A) and is in contact with an encapsulant 320, defects such as peeling, a void, or the like may occur between the encapsulant 320 and the adhesive layer 142. According to an example embodiment, the cover layer 150 may completely cover the adhesive layer 142 that would otherwise be exposed from the mold 143, to prevent contact between the encapsulant 320 and the adhesive layer 142, and improve reliability of the semiconductor package 300B. A first uppermost surface of the adhesive layer 142 may be in contact with the first surface S1 of the cover layer 150. The mold 143 may surround an external side surface of the adhesive layer 142. A second uppermost surface of the mold 143 may be in contact with the first surface S1 of the cover layer 150. The upper surface of the at least one stacked chip 100b, the first uppermost surface of the adhesive layer 142, and the second uppermost surface of the mold 143 may be on a same surface (i.e., may be coplanar). The upper surface of the at least one stacked chip 100b, the first uppermost surface of the adhesive layer 142, and the second uppermost surface of the mold 143 may correspond to the upper surface of the lower chip structure 100 illustrated in FIG. 1A.

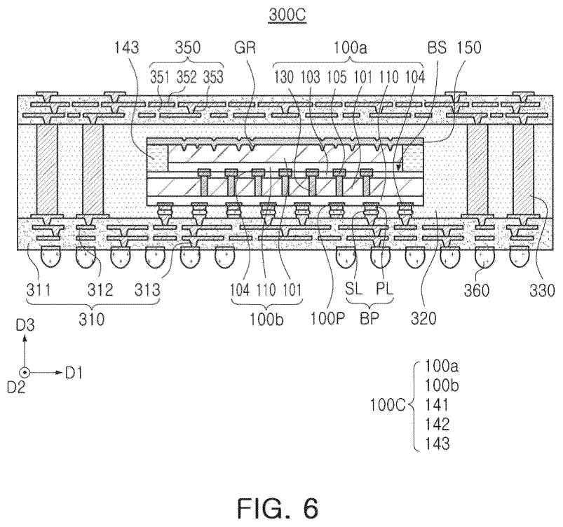

FIG. 6 is a cross-sectional view of a semiconductor package 300C according to an example embodiment.

Referring to FIG. 6, a semiconductor package 300C of an example embodiment may have the same or similar features as those described with reference to FIGS. 1A to 5B, except that a lower chip structure (or ‘chip structure’) 100C in which a base chip 100a and stacked chips 100b are directly joined and coupled.

The chip structure 100C may include the base chip 100a, the at least one stacked chip 100b, and the mold 143. The base chip 100a and the at least one stacked chip 100b may be directly joined and coupled without a separate connecting member (e.g., solder bump, copper pillar, or the like). The chip structure 100C may include a bonding surface BS in which an upper surface of the base chip 100a and a lower surface of the at least one stacked chip 100b are joined. The bonding surface BS may be formed by metal bonding or dielectric bonding. The upper pad 105 of the base chip 100a and the lower pad 104 of the stacked chip 100b may include copper (Cu). The upper protective layer 103 surrounding the upper pad 105 of the base chip 100a and the dielectric layer surrounding the lower pad 104 of the stacked chip 100b may include a material that may be joined and coupled to each other, for example, at least one of silicon oxide (SiO), silicon nitride (SiN), or silicon carbonitride (SiCN).

FIG. 7 is a cross-sectional view of a semiconductor package 300D according to an example embodiment.

Referring to FIG. 7, a semiconductor package 300D of an example embodiment may have the same or similar features as those described with reference to FIGS. 1A to 6, except that an upper chip structure 200 and/or a heat dissipation member 340 may be further included.

The upper chip structure 200 may be a bare chip or a packaged chip on which a logic circuit or a memory circuit is formed. According to an embodiment, the upper chip structure 200 may be a package structure in which a plurality of semiconductor chips are mounted on a substrate. The upper chip structure 200 may include a different type of a semiconductor chip, different from the semiconductor chip of the lower chip structure 100. For example, the lower chip structure 100 may include a logic chip, and the upper chip structure 200 may include a memory chip.

The upper chip structure 200 may be disposed on the upper redistribution structure 350. The upper chip structure 200 may be electrically connected to the lower redistribution layer 312 through the plurality of posts 330. According to an embodiment, the plurality of posts 330 may be arranged in a position overlapping the upper chip structure 200 in the vertical direction D3. The upper chip structure 200 may include second connection terminals 200P electrically connected to the plurality of posts 330. The second connection terminals 200P may be connected to the plurality of posts 330 through upper connection bumps 250 disposed between the upper chip structure 200 and the plurality of posts 330. The upper chip structure 200 may be electrically connected to the lower chip structure 100 through the lower redistribution layer 312 and the plurality of posts 330. According to an embodiment, an insulating material layer surrounding the upper connection bumps 250 may be formed under the upper chip structure 200.

The heat dissipation member 340 may be disposed on at least one side of the upper chip structure 200. The heat dissipation member 340 may overlap at least a portion of the lower chip structure 100 in the vertical direction (D3 direction). According to an embodiment, the heat dissipation member 340 may have a shape surrounding four sides of the upper chip structure 200. The heat dissipation member 340 may control warpage of the semiconductor package 300D, and may emit heat generated from the lower chip structure 100 externally.

The heat dissipation member 340 may include a heat transfer material layer (thermal interface material, TIM) 341 and a heat slug 342. The heat transfer material layer 341 may include, for example, a heat conductive adhesive tape, a heat conductive grease, a heat conductive adhesive, or the like. The heat slug 342 may be disposed on heat transfer material layer 341. The heat slug 342 may include a material having excellent thermal conductivity, such as aluminum (Al), gold (Au), silver (Ag), copper (Cu), iron (Fe), graphite, graphene, or the like.

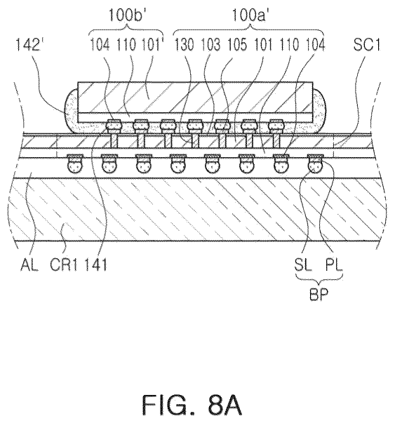

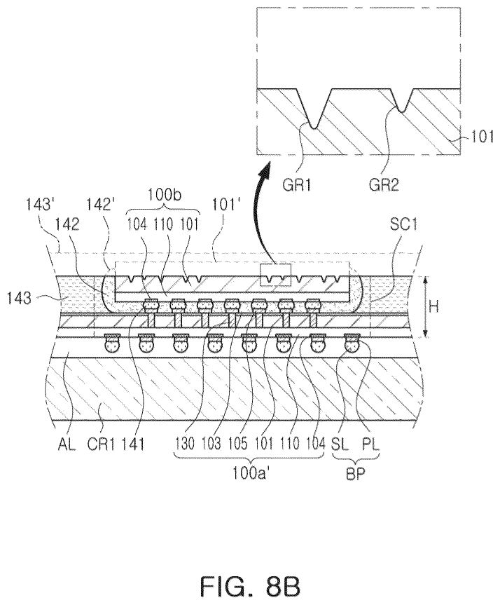

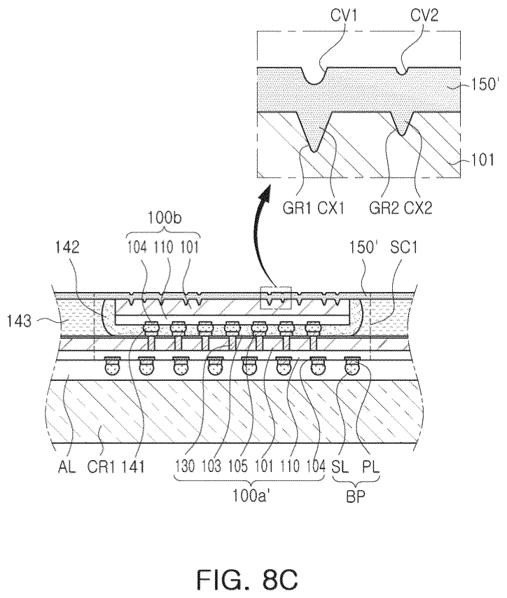

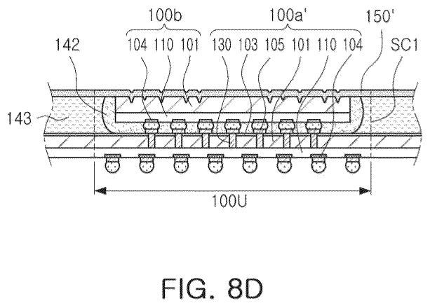

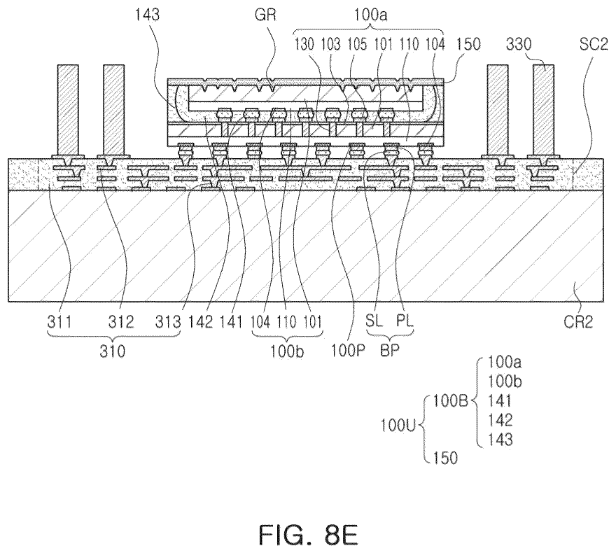

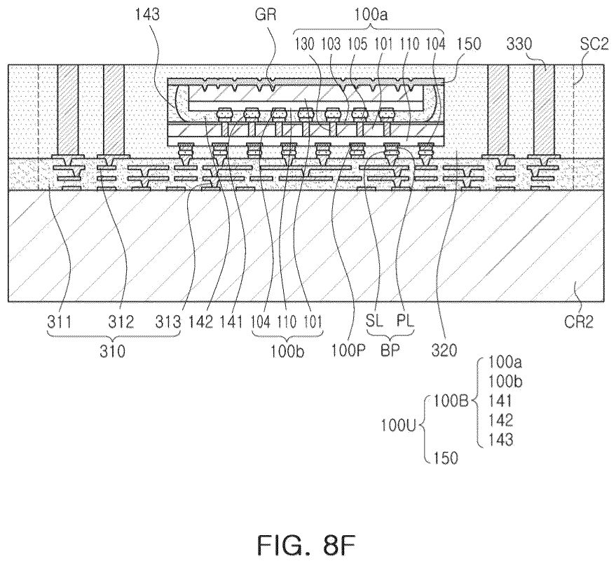

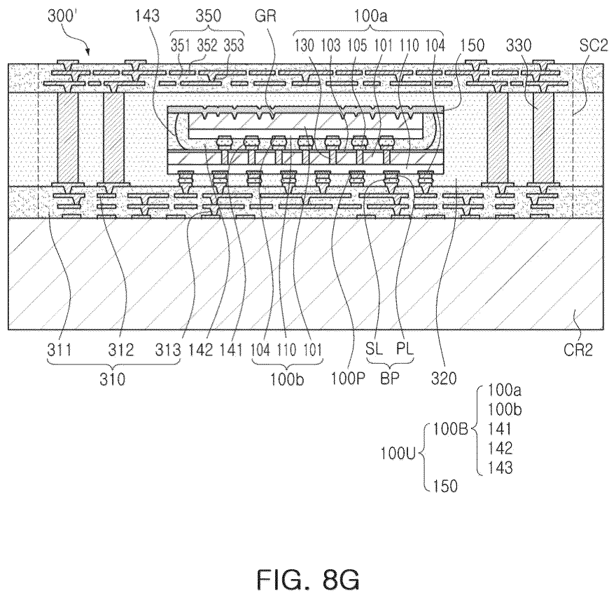

FIGS. 8A to 8G are views illustrating a process of manufacturing a semiconductor package according to an example embodiment. FIGS. 8A to 8G illustrate a process of manufacturing the semiconductor package 300B illustrated in FIGS. 5A and 5B in a process order.

Referring to FIG. 8A, a preliminary stacked chip 100b′ may be disposed on a semiconductor wafer 100a′. The semiconductor wafer 100a′ may include a plurality of base chips divided by a scribe lane SC1. The semiconductor wafer 100a′ may include elements constituting a base chip, for example, a substrate 101, an upper protective layer 103, an upper pad 105, a circuit layer 110, a lower pad 104, and a through-via 130. The semiconductor wafer 100a′ may be temporarily attached to a first carrier substrate CR1 by an adhesive material layer AL.

The preliminary stacked chip 100b′ may include a preliminary substrate 101′, a circuit layer 110, and a lower pad 104. The preliminary stacked chip 100b′ may be electrically connected to the semiconductor wafer 100a′ through bumps 141. The preliminary stacked chip 100b′ may be disposed on the semiconductor wafer 100a′ by a pick-and-place device. The preliminary stacked chip 100b′ may be attached to the semiconductor wafer 100a′ by performing a thermal compression process. In the thermal compression process, an adhesive film layer 142′ may be formed to cover an external side surface of the preliminary stacked chip 100b′.

Referring to FIG. 8B, a mold layer 143′ covering the preliminary stacked chip 100b′ may be formed, and a back grinding process may be applied to form a stacked chip 100b having a required thickness. At least a portion of the mold layer 143′, at least a portion of the adhesive film layer 142′, and at least a portion of the preliminary substrate 101′ may be removed by a back grinding process. The back grinding process may be performed such that a height (H) of the stacked chip 100b and the semiconductor wafer 100a′ may be about 300 μm or less. In the back grinding process, wheel scratches, for example, a plurality of grooves GR1 and GR2, may be formed on an upper surface of the stacked chip 100b.

Referring to FIG. 8C, a cover material layer 150′ may be formed on the stacked chip 100b, an adhesive layer 142, and a mold 143. The cover material layer 150′ may be formed by a deposition process such as PVD or CVD, or a spin coating process. The cover material layer 150′ may include silicon oxide (SiO), silicon nitride (SiN), silicon carbonitride (SiCN), and combinations thereof. According to an embodiment, the cover material layer 150′ may include a polymer having improved heat dissipation characteristics. The cover material layer 150′ may extend along internal surfaces of the plurality of grooves GR1 and GR2 of the stacked chip 100b. A thickness of the cover material layer 150′ may range from about 5 μm to about 10 μm, but is not limited thereto. The cover material layer 150′ may include convex portions CX1 and CX2 filling the plurality of grooves GR1 and GR2, and concave portions CV1 and CV2 aligned on at least one of the convex portions CX1 and CX2. A planarization process may be applied to an upper surface of the cover material layer 150′, but embodiments are not limited thereto. The cover material layer 150′ may form the concave portions CV1 and CV2 respectively having a smaller width, a smaller depth, and a smaller curvature, compared to the plurality of grooves GR, to disperse stress concentrated in the plurality of grooves GR and prevent occurrence of a crack.

Referring to FIG. 8D, the cover material layer 150′, the mold 143, and the semiconductor wafer 100a′ may be cut along the scribe lane SC1 to separate unit structures 100U. It can be understood that the unit structures 100U are the same as the lower chip structure 100B illustrated in FIGS. 5A and 5B. The cover material layer 150′ or the cover layer (‘150’ in FIG. 8E) may prevent occurrence of defects such as a crack in the unit structures 100U, peeling of the encapsulant (‘320’ in FIG. 8F), or the like that may occur in subsequent processes, to improve reliability and yield of the package.

Referring to FIG. 8E, the unit structure 100U may be mounted on a lower redistribution structure 310. The lower redistribution structure 310 may be formed on a second carrier substrate CR2. The lower redistribution structure 310 may be formed on a wafer level or a panel level. The lower redistribution structure 310 may include a lower insulating layer 311, a lower redistribution layer 312, and a lower redistribution via 313. The lower insulating layer 311 may be formed by sequentially applying and curing a photosensitive material, for example, PID. The lower redistribution layer 312 and the lower redistribution via 313 be formed by performing an exposure process and a development process to form a via hole passing through the lower insulating layer 311, and patterning a metal material on the lower insulating layer 311 using a plating process. A plurality of posts 330 may be formed on the lower redistribution structure 310. The plurality of posts 330 may be formed by performing a plating process.

Referring to FIG. 8F, an encapsulant 320 may be formed on the lower redistribution structure 310. The encapsulant 320 may cover at least a portion of the lower chip structure 100 and at least a portion of the posts 330. The encapsulant 320 may be formed to cover an upper surface of the cover layer 150. The cover layer 150 may prevent formation of an interface between the encapsulant 320 and the adhesive layer 142. A planarization process may be applied to the encapsulant 320 such that upper ends of the plurality of posts 330 are exposed. The planarization process may include a grinding process, a chemical mechanical polishing (CMP) process, or the like. The encapsulant 320 may include, for example, EMC, and may be formed by a molded underfill (MUF) process. According to an embodiment, a capillary underfill (CUF) may be formed between the unit structure 100U and the lower redistribution structure 310.

Referring to FIG. 8G, an upper redistribution structure 350 may be formed on the encapsulant 320. The upper redistribution structure 350 may include an upper insulating layer 351, an upper redistribution layer 352, and an upper redistribution via 353. Thereafter, unit packages 300′ may be separated by cutting the lower redistribution structure 310, the encapsulant 320, and the upper redistribution structure 350 along a scribe lane SC2.

According to various embodiments, a cover layer may be introduced on an upper surface of a chip structure to which back grinding is applied, to provide a semiconductor package having improved reliability.

Various advantages and effects of the embodiments are not limited to the above-described contents, and can be more easily understood through description of specific embodiments.

While various example embodiments have been illustrated and described above, it will be apparent to those skilled in the art that modifications and variations could be made without departing from the scope of the present disclosure as defined by the appended claims.

What is claimed is:

1. A semiconductor package comprising:
a lower redistribution structure including a lower redistribution layer;
a lower chip structure disposed on the lower redistribution structure;
a cover layer including a first surface that contacts the lower chip structure and a second surface that is opposite to the first surface;
an encapsulant encapsulating at least a portion of the lower chip structure and at least a portion of the cover layer;
an upper redistribution structure disposed on the encapsulant and including an upper redistribution layer;
a plurality of posts that pass through the encapsulant and electrically connect the lower redistribution layer and the upper redistribution layer; and
a plurality of external connection bumps that are disposed below the lower redistribution structure and electrically connect to the lower redistribution layer,
wherein the lower chip structure includes:
at least one stacked chip that contacts the first surface of the cover layer and has an upper surface having a plurality of grooves;
a base chip disposed below the at least one stacked chip, the base chip including through-vias electrically connected to the at least one stacked chip and connection pads electrically connected to the lower redistribution layer;
an adhesive layer disposed between the at least one stacked chip and the base chip and extending to the first surface of the cover layer along a side surface of the at least one stacked chip; and
a mold surrounding an external side surface of the adhesive layer,
wherein the cover layer includes a plurality of convex portions on the first surface that fill the plurality of grooves, and at least one concave portion on the second surface that is aligned on at least one convex portion among the plurality of convex portions.

2. The semiconductor package of claim 1, wherein the plurality of grooves comprise a first groove extending in a first direction, and
the at least one concave portion comprises a first concave portion aligned on the first groove.

3. The semiconductor package of claim 2, wherein a width of the first concave portion in a second direction that is perpendicular to the first direction is less than a width of the first groove in the second direction.

4. The semiconductor package of claim 2, wherein a depth of the first concave portion in a third direction that is perpendicular to the second surface is less than a depth of the first groove in the third direction.

5. The semiconductor package of claim 2, wherein a depth-to-width ratio of the first concave portion is less than a depth-to-width ratio of the first groove.

6. The semiconductor package of claim 1, wherein the plurality of grooves comprise a first groove and a second groove, each having a depth that is smaller than a depth of the first groove,
wherein the at least one concave portion includes a first concave portion that is aligned on the first groove and a second concave portion that is aligned on the second groove, and
wherein a depth of the second concave portion is less than a depth of the first concave portion.

7. The semiconductor package of claim 1, wherein the plurality of grooves comprise a first groove and a second groove that has a depth that is less than a depth of the first groove, and
wherein the at least one concave portion includes one concave portion, and the one concave portion is aligned on the first groove.

8. The semiconductor package of claim 1, wherein the adhesive layer further comprises a first uppermost surface that contacts the first surface of the cover layer, and
the mold further comprises a second uppermost surface that contacts the first surface of the cover layer.

9. The semiconductor package of claim 8, wherein the upper surface of the at least one stacked chip, the first uppermost surface of the adhesive layer, and the second uppermost surface of the mold are coplanar.

10. The semiconductor package of claim 1, wherein the cover layer comprises at least one of silicon oxide (SiO), silicon nitride (SiN), or a polymer.

11. The semiconductor package of claim 10, wherein the cover layer comprises the polymer, and
wherein the polymer comprises an insulating resin and a thermally conductive filler dispersed in the insulating resin.

12. The semiconductor package of claim 1, wherein the lower chip structure further comprises a plurality of connection bumps that connect the connection pads of the base chip to the lower redistribution layer.

13. The semiconductor package of claim 12, wherein each of the plurality of connection bumps comprise a pillar portion that contacts a respective one of the connection pads and a solder portion that is disposed below the pillar portion.

14. The semiconductor package of claim 1, further comprising:
an upper chip structure disposed on the upper redistribution structure; and
a heat dissipation member disposed on at least one side of the upper chip structure.

15. A semiconductor package comprising:
a redistribution structure including a redistribution layer;
a chip structure electrically connected to the redistribution layer and having an upper surface having a plurality of grooves;
a cover layer including a first surface that contacts the upper surface of the chip structure, and a second surface that is opposite to the first surface and has at least one concave portion that is aligned with at least one groove among the plurality of grooves;
an encapsulant encapsulating at least a portion of the chip structure and at least a portion of the cover layer; and
a plurality of external connection bumps that are disposed below the redistribution structure and electrically connect to the redistribution layer,
wherein the plurality of grooves include a first groove having a first curvature,
the at least one concave portion includes a first concave portion that is aligned on the first groove, and
the first concave portion has a second curvature that is smaller than the first curvature.

16. The semiconductor package of claim 15, wherein the chip structure comprises:
at least one stacked chip having the plurality of grooves,
a base chip disposed below the at least one stacked chip,
an adhesive layer disposed between the at least one stacked chip and the base chip and surrounding a side surface of the at least one stacked chip, and
a mold surrounding an external side surface of the adhesive layer.

17. The semiconductor package of claim 16, wherein an upper surface of the at least one stacked chip, an upper surface of the adhesive layer, and an upper surface of the mold corresponds to the upper surface of the chip structure, and
the first surface of the cover layer is entirely in contact with the upper surface of the chip structure.

18. A semiconductor package comprising:
a lower redistribution structure including a lower redistribution layer;
a lower chip structure including a lower surface on which connection terminals that are electrically connected to the lower redistribution layer are disposed, and an upper surface having a plurality of grooves;
a cover layer including a first surface that contacts the upper surface of the lower chip structure, and a second surface that is opposite to the first surface and has at least one concave portion that is aligned with at least one groove among the plurality of grooves;
an encapsulant encapsulating at least a portion of the lower chip structure and at least a portion of the cover layer;
an upper redistribution structure disposed on the encapsulant and including an upper redistribution layer; and
a plurality of posts that pass through the encapsulant and electrically connect the lower redistribution layer to the upper redistribution layer.

19. The semiconductor package of claim 18, wherein a height from the lower surface of the lower chip structure to the upper surface of the lower chip structure is about 300 μm or less.

20. The semiconductor package of claim 18, wherein the plurality of grooves comprise a first groove having a first curvature,
the at least one concave portion comprises a first concave portion that is aligned on the first groove, and
the first concave portion has a second curvature that is different from the first curvature.
